(19) United States
(12) Patent Application Publication
(10) Pub. No.: US 2012/0276413 A1
(43) Pub. Date: Nov. 1, 2012

(54) PROCESS FOR SURFACE TREATING IRON-BASED ALLOY AND ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); YING-YING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/217,936

(22) Filed: Aug. 25, 2011

(30) Foreign Application Priority Data
Apr. 27, 2011 (CN) 201110106351.7

(51) Int. Cl. C23C 14/35; B32B 15/00; C23C 14/06

(52) U.S. Cl. 428/685; 204/192.15; 428/684; 428/681

(57) ABSTRACT

A process for surface treating iron-based alloy includes providing a substrate made of iron-based alloy. A chromium-oxygen-nitrogen layer is then formed on the substrate by sputtering. An iridium layer is formed on the chromium-oxygen-nitrogen layer by sputtering. A boron-nitrogen layer is next formed on the iridium layer by sputtering.

### CROSS-REFERENCE TO RELATED APPLICATIONS

This application is related to co-pending U.S. patent applications (Attorney Docket No. US39242 and US39244, each entitled “PROCESS FOR SURFACE TREATING IRON-BASED ALLOY AND ARTICLE”, each invented by Chang et al. These applications have the same assignee as the present application. The above-identified applications are incorporated herein by reference.

### BACKGROUND

1. Technical Field

The disclosure generally relates to a process for surface treating iron-based alloy, and articles made of iron-based alloy treated by the process.

2. Description of Related Art

Articles made of iron-based alloy, such as die steel are often subjected to oxidation when used in high temperatures. Oxide films resulting from oxidation can damage the quality of the surfaces of the articles. Furthermore, during repeated use, the oxide films can break off, exposing an underneath iron-based alloy substrate. The exposed iron-based alloy substrate is further subjected to oxidation. Thus, the service life of the articles may be reduced.

Therefore, there is room for improvement within the art.

### BRIEF DESCRIPTION OF THE FIGURES

Many aspects of the coated article can be better understood with reference to the following figures. The components in the figures are not necessarily drawn to scale, the emphasis instead being placed upon clearly illustrating the principles of the exemplary process for the surface treating of iron-based alloy and articles made of iron-based alloy treated by the process. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated in accordance with the present process.

FIG. 2 is a schematic view of a vacuum sputtering machine for processing the exemplary article shown in FIG. 1.

### DETAILED DESCRIPTION

An exemplary process for the surface treatment of iron-based alloy may include the following steps:

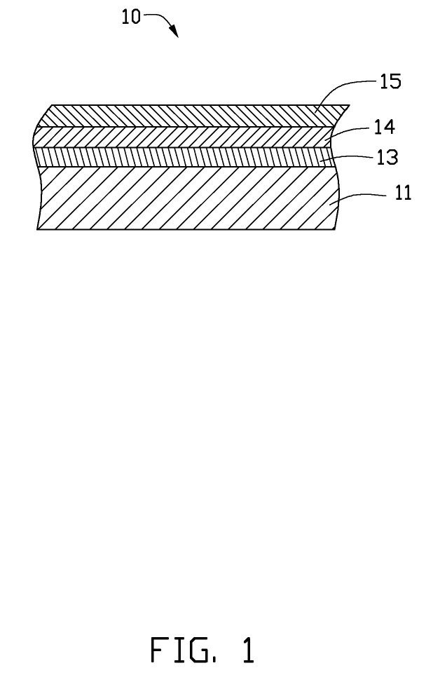

Referring to FIG. 1, a substrate 11 is provided. The substrate 11 is made of an iron-based alloy, such as cutlery steel, die steel, gauge steel, or stainless steel containing chromium.

The substrate 11 is pretreated. The substrate 11 is cleaned with a solution (e.g., alcohol or acetone) in an ultrasonic cleaner, to remove impurities such as grease or dirt from the substrate 11. Then, the substrate 11 is dried.

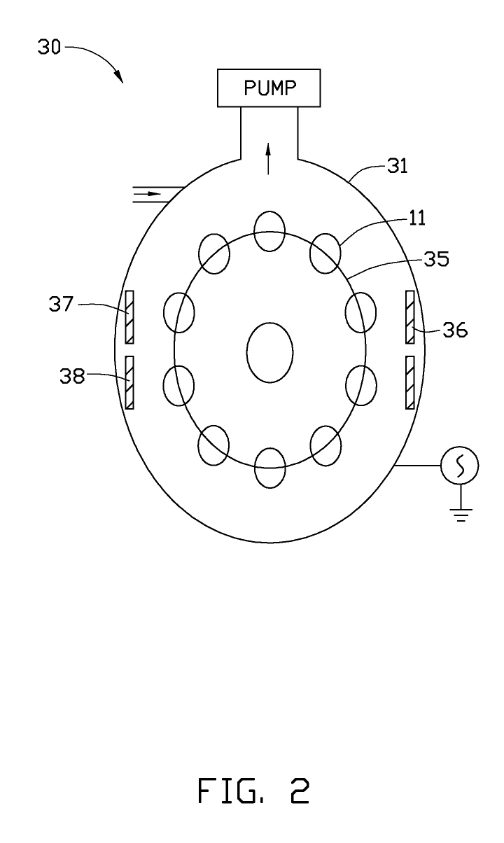

The substrate 11 is plasma cleaned. Referring to FIG. 2, the substrate 11 may be held on a rotating bracket 35 in a vacuum chamber 31 of a vacuum sputtering machine 30. In this exemplary, the vacuum sputtering machine 30 is a DC magnetron sputtering machine. The vacuum chamber 31 is fixed with a chromium target 36, an iridium target 37, and a boron target 38 therein. The vacuum chamber 31 is then evacuated to a vacuum level of about 3×10⁻⁵ torr −6×10⁻⁵ torr and maintains the same vacuum level throughout the following steps. Argon (Ar, having a purity of about 99.999%) is fed into the vacuum chamber 31 at a flow rate of about 100 standard-state cubic centimeters per minute (sccm) to 400 sccm. A bias voltage of about −200 V to about −300 V is applied to the substrate 11. Ar is ionized to plasma. The plasma then strikes the surface of the substrate 11 to clean the surface of the substrate 11 further. The plasma cleaning of the substrate 11 may take about 3 minutes (min) to 20 min. The plasma cleaning process enhances the bond between the substrate 11 and a subsequently formed layer. The chromium target 36, iridium target 37, and boron target 38 are unaffected by the plasma cleaning process.

A chromium-oxygen-nitrogen (CrON) layer 13 is formed on the pretreated substrate 11 by vacuum sputtering. Sputtering of the CrON layer 13 is implemented in the vacuum chamber 31. The internal temperature of the vacuum chamber 31 may be controlled at about 20° C.-200° C. Argon, oxygen, and nitrogen are simultaneously fed into the vacuum chamber 31, with the argon acting as a sputtering gas and the oxygen and nitrogen acting as reaction gases. The flow rate of the argon is about 100 sccm-300 sccm. The flow rate of the oxygen is about 50 sccm-300 sccm. The flow rate of nitrogen is about 20 sccm-100 sccm. The bias voltage applied to the substrate 11 is adjusted in a range between about −100 V and about −300 V. About 8 kW-12 kW of power is applied to the chromium target 36, depositing the CrON layer 13 on the substrate 11. The deposition of the CrON layer 13 may take about 3 min-20 min.

An iridium layer 14 is directly formed on the CrON layer 13 by vacuum sputtering. Sputtering of the iridium layer 14 is implemented in the vacuum chamber 31. The chromium target 36 is switched off. The internal temperature of the vacuum chamber 31 may be controlled at about 20° C.-200° C. The flow rate of argon is maintained at about 100 sccm-300 sccm. Oxygen and nitrogen are stopped feeding into the vacuum chamber 31. A bias voltage of about −100 V to about −300 V may be applied to the substrate 11. About 8 kW-12 kW of power is applied to the iridium target 37, depositing the iridium layer 14 on the CrON layer 13. The deposition of the iridium layer 14 may take about 10 min-50 min.

A boron-nitrogen (BN) layer 15 is then directly formed on the iridium layer 14 by vacuum sputtering. Sputtering of the BN layer 15 is implemented in the vacuum chamber 31. The iridium target 37 is switched off. The internal temperature of the vacuum chamber 31 may be controlled at about 20° C.-200° C. Argon and nitrogen are simultaneously fed into the vacuum chamber 31, with the argon acting as a sputtering gas and the nitrogen acting as a reaction gas. The flow rate of argon is about 100 sccm-300 sccm. The flow rate of nitrogen is about 20 sccm-100 sccm. A bias voltage of about −100 V to about −300 V may be applied to the substrate 11. About 10 kW-13 kW of power is applied to the boron target 38, depositing the BN layer 15 on the iridium layer 14. The deposition of the BN layer 15 may take about 10 min-50 min.

FIG. 1 shows a cross-section of an exemplary article 10 made of iron-based alloy and processed by the surface treatment process described above. The article 10 includes the substrate 11 having the CrON layer 13, the iridium layer 14, and the BN layer 15 formed thereon, and in that order. The thickness of the CrON layer 13 may be about 20 nm-50 nm. The thickness of the iridium layer 14 may be about 80 nm-150 nm. The thickness of the BN layer 15 may be about 100 nm-200 nm.

The CrON layer 13, which has a high density and a high melting point can prevent from oxygen entering the CrON layer 13, and can prevent atoms having a relatively large diameter, such as Nb, Ti, Al, Si, and Cr from interdiffusing between the substrate 11 and layers thereon, thus protecting the substrate 11 from oxidation. The iridium layer 14 has a good stability in high temperatures and can maintain a good mechanical property under a temperature above 1600° C. The BN layer 15 has a good lubricity. Thus, when the article 10 used as a mold, the mold can be easily separated from molded articles.

### EXAMPLES

Specific examples of the present disclosure are described as follows. The pretreatment in these specific examples may be substantially the same as described above so it is not described here again. The specific examples mainly emphasize the different process parameters of the process for the surface treatment of iron-based alloy.

### Example 1

The substrate 11 is made of a S316 type die steel. The vacuum chamber 31 maintains a vacuum level of about 3×10⁻⁵ ton.

Plasma cleaning the substrate 11: the flow rate of argon is 200 sccm; a bias voltage of −300 V is applied to the substrate 11; the plasma cleaning of the substrate 11 takes 5 min.

Sputtering to form CrON layer 13 on the substrate 11: the flow rate of argon is 150 sccm, the flow rate of nitrogen is 30 sccm, the flow rate of oxygen is 50 sccm; the internal temperature of the vacuum chamber 31 is 30° C.; a bias voltage of −150 V is applied to the substrate 11; about 8 kW of power is applied to the chromium target 36; sputtering of the CrON layer 13 takes 6 min; the CrON layer 13 has a thickness of 25 nm.

Sputtering to form iridium layer 14 on the CrON layer 13: the flow rate of argon is 150 sccm; the internal temperature of the vacuum chamber 31 is 30° C.; a bias voltage of −150 V is applied to the substrate 11; about 8 kW of power is applied to the iridium target 37; sputtering of the iridium layer 14 takes 15 min; the iridium layer 14 has a thickness of about 90 nm.

Sputtering to form BN layer 15 on the iridium layer 14: the flow rate of argon is 150 sccm; the flow rate of nitrogen is 40 sccm; the internal temperature of the vacuum chamber 31 is 30° C.; a bias voltage of −150 V is applied to the substrate 11; about 10 kW of power is applied to the boron target 38; sputtering of the BN layer 15 takes 30 min; the BN layer 15 has a thickness of 120 nm.

### Example 2

The substrate 11 is made of a H11 type die steel. The vacuum chamber 31 maintains a vacuum level of about 3×10^{31 5} torr.

Plasma cleaning the substrate 11: the flow rate of argon is 300 sccm; a bias voltage of −200 V is applied to the substrate 11; the plasma cleaning of the substrate 11 takes 10 min.

Sputtering to form CrON layer 13 on the substrate 11: the flow rate of argon is 200 sccm, the flow rate of nitrogen is 50 sccm, the flow rate of oxygen is 80 sccm; the internal temperature of the vacuum chamber 31 is 100° C.; a bias voltage of −200 V is applied to the substrate 11; about 11 kW of power is applied to the chromium target 36; sputtering of the CrON layer 13 takes 15 min; the CrON layer 13 has a thickness of 40 nm.

Sputtering to form iridium layer 14 on the CrON layer 13: the flow rate of argon is 200 sccm; the internal temperature of the vacuum chamber 31 is 100° C.; a bias voltage of −200 V is applied to the substrate 11; about 11 kW of power is applied to the iridium target 37; sputtering of the iridium layer 14 takes 30 min; the iridium layer 14 has a thickness of about 120 nm.

Sputtering to form BN layer 15 on the iridium layer 14: the flow rate of argon is 150 sccm; the flow rate of nitrogen is 70 sccm; the internal temperature of the vacuum chamber 31 is 100° C.; a bias voltage of −200 V is applied to the substrate 11; about 13 kW of power is applied to the boron target 38; sputtering of the BN layer 15 takes 50 min; the BN layer 15 has a thickness of 140 nm.

### Example 3

The substrate 11 is made of a P20 type die steel. The vacuum chamber 31 maintains a vacuum level of about 3×10⁻⁵ torr.

Plasma cleaning the substrate 11: the flow rate of argon is 300 sccm; a bias voltage of −200 V is applied to the substrate 11; the plasma cleaning of the substrate 11 takes 10 min.

Sputtering to form CrON layer 13 on the substrate 11: the flow rate of argon is 200 sccm, the flow rate of nitrogen is 100 sccm, the flow rate of oxygen is 100 sccm; the internal temperature of the vacuum chamber 31 is 150° C.; a bias voltage of −200 V is applied to the substrate 11; about 10 kW of power is applied to the chromium target 36; sputtering of the CrON layer 13 takes 20 min; the CrON layer 13 has a thickness of 50 nm.

Sputtering to form iridium layer 14 on the CrON layer 13: the flow rate of argon is 200 sccm; the internal temperature of the vacuum chamber 31 is 150° C.; a bias voltage of −200 V is applied to the substrate 11; about 10 kW of power is applied to the iridium target 37; sputtering of the iridium layer 14 takes 60 min; the iridium layer 14 has a thickness of about 150 nm.

Sputtering to form BN layer 15 on the iridium layer 14: the flow rate of argon is 200 sccm; the flow rate of nitrogen is 200 sccm; the internal temperature of the vacuum chamber 31 is 150° C.; a bias voltage of −200 V is applied to the substrate 11; about 11 kW of power is applied to the boron target 38; sputtering of the BN layer 15 takes 60 min; the BN layer 15 has a thickness of 160 nm.

An oxidation test at high temperature was applied to the samples created by examples 1-3. The test was carried out in an air atmosphere. The samples were retained in a high temperature oven for about 1 hour and then were removed. The oven maintained an internal temperature of about 800° C. Neither oxidation nor peeling was found with the samples created by examples 1-3.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A process for surface treating iron-based alloy, the process comprising the following steps of:
providing a substrate made of iron-based alloy;
forming a chromium-oxygen-nitrogen layer on the substrate by sputtering;
forming a iridium layer on the chromium-oxygen-nitrogen layer by sputtering; and
forming a boron-nitrogen layer on the iridium layer by sputtering.

2. The process as claimed in claim 1, wherein sputtering of the chromium-oxygen-nitrogen layer uses argon at a flow rate of about 100 sccm-300 sccm as a puttering gas, uses nitrogen at flow rate of about 20 sccm-100 sccm and oxygen at a flow rate of about 50 sccm-300 sccm as reaction gases; uses a chromium target and applies about 8 kW-12 kW of power to the chromium target; applies a bias voltage of about −100 V to about −300 V to the substrate; sputtering of the chromium-oxygen-nitrogen layer is conducted at a temperature of about 20° C.-200° C. and takes about 3 min-20 min.

3. The process as claimed in claim 1, wherein sputtering of the iridium layer uses argon at a flow rate of about 100 sccm-300 sccm as a puttering gas; uses an iridium target and applies about 8 kW-12 kW of power to the iridium target; applies a bias voltage of about −100 V to about −300 V to the substrate; sputtering of the iridium layer is conducted at a temperature of about 20° C.-200° C. and takes about 10 min-50 min.

4. The process as claimed in claim 1, wherein sputtering of the boron-nitrogen layer uses argon at a flow rate of about 100 sccm-300 sccm as a puttering gas; uses nitrogen at a flow rate of about 20 sccm-100 sccm as a reaction gas, uses an iridium target and applies about 10 kW-13 kW of power to the boron target; applies a bias voltage of about −100 V to about −300 V to the substrate; sputtering of the boron-nitrogen layer is conducted at a temperature of about 20° C.-200° C. and takes about 10 min-50 min.

5. The process as claimed in claim 1, further comprising a step of plasma cleaning the substrate, before forming the chromium-oxygen-nitrogen layer.

6. An article, comprising:
a substrate made of iron-based alloy;
a chromium-oxygen-nitrogen layer formed on the substrate;
an iridium layer formed on the chromium-oxygen-nitrogen layer; and
a boron-nitrogen layer formed on the iridium layer.

7. The article as claimed in claim 6, wherein the chromium-oxygen-nitrogen layer has a thickness of about 20 nm-50 nm.

8. The article as claimed in claim 6, wherein the iridium layer has a thickness of about 80 nm-150 nm.

9. The article as claimed in claim 6, wherein the boron-nitrogen layer has a thickness of about 100 nm-200 nm.

10. The article as claimed in claim 6, wherein the chromium-oxygen-nitrogen layer, iridium layer, and boron-nitrogen all are formed by sputtering.

11. The article as claimed in claim 6, wherein the substrate is made of a material selected from the group consisting of cutlery steel, die steel, gauge steel, and stainless steel containing chromium.
